(19) United States
(12) Patent Application Publication
(10) Pub. No.: US 2010/0139766 A1
(43) Pub. Date: Jun. 10, 2010

(54) PHOTOELECTRIC CONVERSION DEVICE AND METHOD FOR MANUFACTURING THE PHOTOELECTRIC CONVERSION DEVICE

(75) Inventors: Satoshi TORIUMI, Ebina (JP); Toshiya ENDO, Isehara (JP); Eriko OHMORI, Atsugi (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 12/623,888

(22) Filed: Nov. 23, 2009

(30) Foreign Application Priority Data
Nov. 28, 2008 (JP) 2008-303441

(51) Int. Cl. H01L 31/04; H01L 31/00; H01L 31/18

(52) U.S. Cl. 136/258; 438/96; 257/E31.003; 257/E31.032

(57) ABSTRACT

A highly-efficient photoelectric conversion device is provided without complicating the manufacturing process. The photoelectric conversion device includes a unit cell having a semiconductor junction, in which a first impurity semiconductor layer having one conductivity type, a semiconductor layer including a first semiconductor region having a larger proportion of a crystalline semiconductor than an amorphous semiconductor and a second semiconductor region having a larger proportion of an amorphous semiconductor than a crystalline semiconductor and including both a radial crystal and a crystal having a needle-like growing end in the amorphous semiconductor, and a second impurity semiconductor layer having a conductivity type opposite to the conductivity type of the first impurity semiconductor layer are stacked in this order.

### BACKGROUND OF THE INVENTION

1. Field of the Invention

The present invention relates to a photoelectric conversion device and a method for manufacturing the photoelectric conversion device.

2. Description of the Related Art

Research on photoelectric conversion devices and the like including amorphous silicon thin films has been promoted because such photoelectric conversion devices can be manufactured at low cost.

A photoelectric conversion device including an amorphous silicon thin film can be manufactured easily by a plasma CVD apparatus or the like. Therefore, it has been considered that the material and manufacturing costs can be reduced as compared to those of a so-called bulk photoelectric conversion device including single crystal silicon.

However, a photoelectric conversion device including an amorphous silicon thin film has a problem in that when the photoelectric conversion device is continuously exposed to intense light (for example, exposed to sunlight in the midsummer) for a long time, the number of defects such as dangling bonds in the amorphous silicon thin film increases and photogenerated carriers (electrons and holes) are trapped in the defects, so that the photoelectric conversion efficiency drastically decreases. This problem is known as a problem of photodegradation called Staebler-Wronski effect and has hindered the spread of the photoelectric conversion devices including amorphous silicon thin films.

Moreover, a tandem type photoelectric conversion device in which an amorphous silicon thin film and a microcrystalline silicon thin film are stacked is developed because this tandem type photoelectric conversion device can achieve high conversion efficiency. By the stack including the amorphous silicon thin film having sensitivity to short wavelengths and the microcrystalline silicon thin film having sensitivity to long wavelengths, it is expected to expand the wavelength range of light that can be absorbed and to improve the conversion efficiency (for example, see Patent Document 1).

Moreover, it is suggested that higher conversion efficiency is achieved by preventing photodegradation of an amorphous silicon thin film for forming a top cell of a tandem structure (for example, see Patent Document 2). An intermediate layer of metal provided with an opening is provided between a top cell formed using an amorphous silicon thin film and a bottom cell formed using a microcrystalline silicon thin film. Since the intermediate layer of metal reflects light, light can be supplied to the amorphous silicon thin film with high efficiency and the amorphous silicon thin film can be thinned. Moreover, according to Patent Document 2, when the amorphous silicon thin film is thin, a photodegradation phenomenon can be relieved by increasing the internal electric field in an amorphous i-layer.

### REFERENCES

[Patent Document 1] Japanese Published Patent Application No. S60-240167
[Patent Document 1] Japanese Published Patent Application No. 2004-071716

### SUMMARY OF THE INVENTION

By a tandem structure in which a unit cell including an amorphous silicon thin film and a unit cell including a microcrystalline silicon thin film are stacked, the initial conversion efficiency can be increased so as to compensate the decrease in conversion efficiency due to photodegradation. However, in this case, it is necessary to form the unit cell including an amorphous silicon thin film and the unit cell including a microcrystalline silicon thin film; accordingly, the number of steps increases.

In addition, the unit cell including an amorphous silicon thin film includes a number of defects such as dangling bonds, in which the photogenerated carriers are trapped. This causes a problem of a decrease in conversion efficiency. The photodegradation phenomenon can be relieved by the provision of the intermediate layer as disclosed in Patent Document 2; however, a step of forming the intermediate layer is additionally necessary.

In view of the problems as above, it is an object to expand the wavelength range of light that can be utilized and to increase the conversion efficiency of a photoelectric conversion device. It is an object to increase the conversion efficiency without complicating the manufacturing process.

A photoelectric conversion device is provided in which a layer performing photoelectric conversion is a semiconductor layer including a crystalline semiconductor and an amorphous semiconductor, which includes a region having a larger proportion of the crystalline semiconductor than the amorphous semiconductor and a region having a larger proportion of the amorphous semiconductor than the crystalline semiconductor. Moreover, the amorphous semiconductor includes both a radial crystal and a crystal having a needle-like growing end.

An illustrative embodiment of the present invention includes a unit cell including a semiconductor junction, in which a first impurity semiconductor layer having one conductivity type, a semiconductor layer including a first semiconductor region which has a larger proportion of a crystalline semiconductor than an amorphous semiconductor and a second semiconductor region which has a larger proportion of an amorphous semiconductor than a crystalline semiconductor and includes both a radial crystal and a crystal having a needle-like growing end in the amorphous semiconductor, and a second impurity semiconductor layer having a conductivity type opposite to the conductivity type of the first impurity semiconductor layer are stacked in this order.

An illustrative embodiment of the present invention includes a unit cell including a semiconductor junction, in which a first impurity semiconductor layer having one conductivity type, a semiconductor layer including a crystalline semiconductor and an amorphous semiconductor, and a second impurity semiconductor layer having a conductivity type opposite to the conductivity type of the first impurity semiconductor layer are stacked in this order. The semiconductor layer including a crystalline semiconductor and an amorphous semiconductor has a larger proportion of the crystalline semiconductor than the amorphous semiconductor on the first impurity semiconductor layer side, and has a larger proportion of the amorphous semiconductor than the crystalline semiconductor and includes both a radial crystal and a crystal having a needle-like growing end in the amorphous semiconductor on the second impurity semiconductor layer side.

In the above structure, the crystalline semiconductor is preferably a microcrystalline semiconductor.

The radial crystal includes a crystal nucleus and a plurality of portions extending radially from the crystal nucleus. The crystal nucleus can be a single crystal semiconductor and the radially-extending portions can be a microcrystalline semiconductor.

The crystal having a needle-like growing end is preferably a microcrystalline semiconductor.

According to an illustrative embodiment of the present invention, a first electrode is formed over a substrate; a first impurity semiconductor layer having one conductivity type is formed over the first electrode; a semiconductor layer including a crystalline semiconductor and an amorphous semiconductor is formed over the first impurity semiconductor layer in the following manner: a first semiconductor region having a larger proportion of a crystalline semiconductor than an amorphous semiconductor is formed over the first impurity semiconductor layer by introducing a semiconductor source gas and a dilution gas into a reaction chamber with a mixture ratio that allows formation of a microcrystalline semiconductor and generating plasma, a semiconductor particle is formed over the first semiconductor region, and then, a second semiconductor region having a larger proportion of an amorphous semiconductor than a crystalline semiconductor is formed over the first semiconductor region and the semiconductor particle in such a manner that deposition is performed using a semiconductor source gas and a dilution gas with a mixture ratio that allows formation of a microcrystalline semiconductor at an initial stage of the deposition and then using the semiconductor source gas and the dilution gas with a mixture ratio that allows formation of an amorphous semiconductor at a later stage of the deposition by gradually increasing the flow rate of the semiconductor source gas; a second impurity semiconductor layer having a conductivity type opposite to the conductivity type of the first impurity semiconductor layer is formed over the semiconductor layer; and a second electrode is formed over the second impurity semiconductor layer.

In the above structure, by the formation of the second semiconductor region over the first semiconductor region and the semiconductor particle, a crystal having a plurality of portions extending radially and a crystal having a needle-like growing end are formed in the second semiconductor region.

As the semiconductor particle, a silicon microparticle is preferably used.

In this specification, “columnar crystal” refers to an aggregation of a number of crystals or each crystal shape. As the shape of a columnar crystal or each crystal of an aggregation of a number of crystals that form a columnar crystal, a conical shape, a cylindrical shape, a pyramidal shape, a prismatic columnar shape, (including a shape which expands in a growth direction and a shape which narrows in a growth direction) and the like are given. The columnar crystal may be formed by an aggregation of crystals with different sizes, for example, different widths and lengths (side length). The growing end of each crystal may be flat or projected or sharp. Preferably, the columnar crystal is an aggregation of crystals extending in approximately parallel to the film thickness direction.

In this specification, “radial crystal” refers to a crystal having a plurality of portions extending radially from the center, which is a given point, toward the outside. For example, the radial crystal shape can be expressed as being like a sea urchin or a chestnut case. The radial crystal may be an aggregation of a number of crystals. In the case of the radial crystal formed by an aggregation of a number of crystals, each crystal may be a columnar shape, a pyramidal shape, or a conical shape. Each of the plurality of portions extending radially preferably has a needle-like growing end.

The term “photoelectric conversion layer” in this specification includes a semiconductor layer by which a photoelectric effect (internal photoelectric effect) is obtained and moreover includes an impurity semiconductor layer which is joined to form an internal electric field or a semiconductor junction. That is to say, the photoelectric conversion layer in this specification refers to a semiconductor layer having a junction typified by a p-i-n junction or the like.

The term “p-i-n junction” in this specification includes a junction in which a p-type semiconductor layer, an i-type semiconductor layer, and an n-type semiconductor layer are stacked in this order from the light incidence side and a junction in which an n-type semiconductor layer, an i-type semiconductor layer, and a p-type semiconductor layer are stacked in this order from the light incidence side.

Note that the ordinal numbers such as “first”, “second”, and “third” in this specification are used for convenience to distinguish elements. Therefore, these ordinal numbers do not limit the number, the arrangement, and the order of steps.

The wavelength range of light that can be absorbed can be expanded by provision of a semiconductor layer including an amorphous semiconductor and a crystalline semiconductor between an impurity semiconductor layer having one conductivity type and an impurity semiconductor layer having a conductivity type opposite to the one conductivity type. Moreover, when the amorphous semiconductor includes both a radial crystal and a crystal having a needle-like growing end, carriers can be efficiently collected. Thus, the photoelectric conversion efficiency can be improved.

Moreover, a photoelectric conversion device having a semiconductor layer including an amorphous semiconductor and a crystalline semiconductor can be manufactured without complicating the manufacturing process.

### BRIEF DESCRIPTION OF THE DRAWINGS

FIG. 1 is a schematic cross-sectional view illustrating an embodiment of a photoelectric conversion device.

FIGS. 2A to 2C are schematic cross-sectional views illustrating an example of a method for manufacturing the photoelectric conversion device.

FIGS. 3A to 3C are schematic cross-sectional views illustrating an example of a method for manufacturing a photoelectric conversion device module.

FIGS. 4A and 4B are schematic cross-sectional views illustrating an example of a method for manufacturing the photoelectric conversion device module.

FIG. 5 is a cross-sectional STEM image.

### DETAILED DESCRIPTION OF THE INVENTION

Embodiments and Example of the present invention to be disclosed are described below in detail with reference to the drawings. However, the present invention to be disclosed is not limited to the description below, and it is easily understood by those skilled in the art that modes and details can be variously changed without departing from the purpose and the scope of the present invention. Therefore, the present invention is not interpreted as being limited to the description of Embodiments and Example below. Further, in Embodiments and Example described below, the same parts are denoted with the same reference numerals throughout the drawings in some cases.

### Embodiment 1

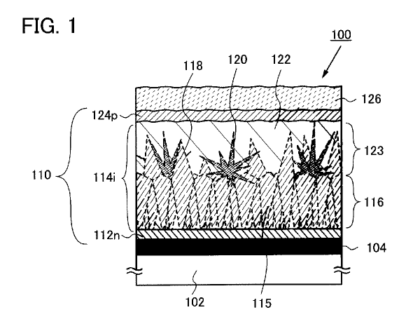

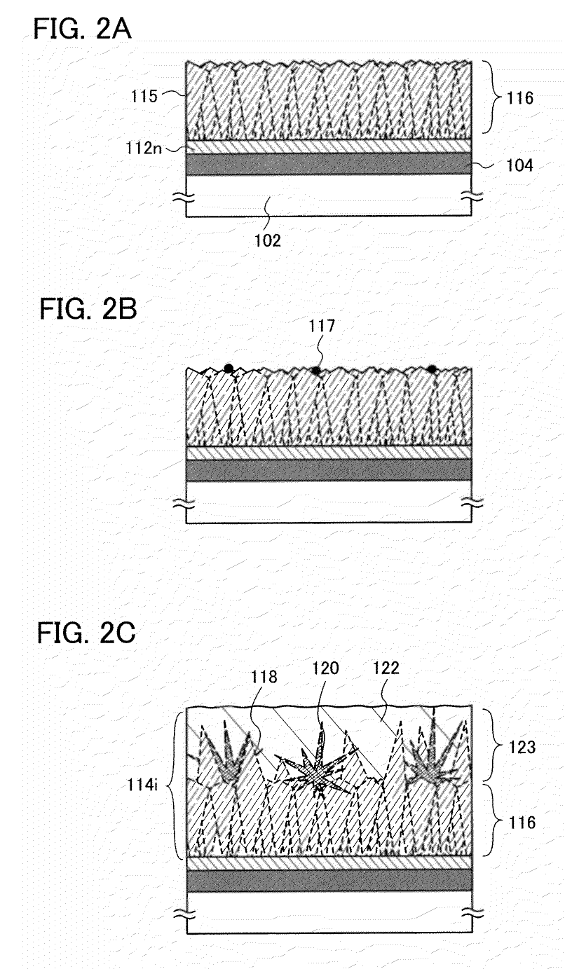

An illustrative embodiment of the present invention is described with reference to FIG. 1 and FIGS. 2A to 2C. A photoelectric conversion device according to Embodiment 1 includes a semiconductor layer performing photoelectric conversion, a substrate supporting the semiconductor layer, and components attached thereto (such as an electrode).

A photoelectric conversion device 100 illustrated in FIG. 1 has a unit cell 110 interposed between a first electrode 104 and a second electrode 126 which are provided over a substrate 102.

In the unit cell 110, a first impurity semiconductor layer 112n having one conductivity type, a semiconductor layer 114i, and a second impurity semiconductor layer 124p having a conductivity type opposite to that of the first impurity semiconductor layer 112n are stacked in this order from the first electrode 104 side. The first impurity semiconductor layer 112n, the semiconductor layer 114i, and the second impurity semiconductor layer 124p form a semiconductor junction typified by a p-i-n junction.

The semiconductor layer 114i has a larger proportion of a crystalline semiconductor than an amorphous semiconductor on the first impurity semiconductor layer 112n side and has a larger proportion of an amorphous semiconductor than a crystalline semiconductor on the second impurity semiconductor layer 124p side. The semiconductor layer 114i includes a crystalline semiconductor such as a columnar crystal 115 on the first impurity semiconductor layer 112n side, and includes both a radial crystal 120 and a crystal 118 having a needle-like growing end in an amorphous structure 122 on the second semiconductor layer 124p side. In Embodiment 1, part of the semiconductor layer 114i which is on the first impurity semiconductor layer 112n side is defined as a first semiconductor region 116 and part of the semiconductor layer 114i which is on the second impurity semiconductor layer 124p side is defined as a second semiconductor region 123.

The first semiconductor region 116 is preferably formed using a microcrystalline semiconductor (typically, microcrystalline silicon) as the crystalline semiconductor. Moreover, FIG. 1 illustrates an example in which the first semiconductor region 116 includes the columnar crystal 115. The columnar crystal 115 is formed using, for example, a microcrystalline semiconductor having a columnar grown structure. Alternatively, a microcrystalline semiconductor having a pyramidal or conical grown structure which expands or narrows in a growth direction may be used. The first semiconductor region 116 can be formed easily by a chemical vapor deposition (CVD) method, typically a plasma CVD method.

In the amorphous structure 122 of the second semiconductor region 123, both the radial crystal 120 and the crystal 118 having a needle-like growing end are included. The radial crystal 120 and the crystal 118 having a needle-like growing end are provided over the first semiconductor region 116, and the amorphous structure 122 is provided so as to cover the radial crystal 120 and the crystal 118 having a needle-like growing end and to fill a space between the radial crystal 120 and the crystal 118 having a needle-like growing end. The amorphous structure 122 includes an amorphous semiconductor, typically amorphous silicon.

The radial crystal 120 is formed using at least one of a microcrystalline semiconductor (typically, microcrystalline silicon), a polycrystalline semiconductor (typically, polycrystalline silicon), and a single crystal semiconductor (typically, single crystal silicon) as the crystalline semiconductor. The radial crystal 120 can be obtained by making a crystal grow from a semiconductor particle (typically a silicon microparticle) serving as a nucleus so as to form a plurality of portions extending radially from the nucleus. Note that the portions extending radially from the radial crystal 120 may enter the first semiconductor region 116.

The crystal 118 having a needle-like growing end is preferably formed using a microcrystalline semiconductor (typically, microcrystalline silicon) as the crystalline semiconductor. The crystal 118 having a needle-like growing end can be obtained by making a crystal grow by using the first semiconductor region 116 below the crystal 118 as a seed crystal. The crystal 118 having a needle-like growing end extends in approximately parallel to the film thickness direction; in FIG. 1, the crystal 118 extends in approximately parallel to the growth direction of the columnar crystal 115.

The semiconductor layer 114i is a main layer for performing photoelectric conversion. Here, the semiconductor layer 114i includes the first semiconductor region 116 including a crystalline semiconductor and the second semiconductor region 123 including a crystalline semiconductor in an amorphous semiconductor. The first semiconductor region 116 including a crystalline semiconductor has sensitivity to long wavelengths and the second semiconductor region 123 including an amorphous semiconductor has sensitivity to shorter wavelengths than the first semiconductor region 116. Therefore, the wavelength range of light that can be absorbed by the semiconductor layer 114i can be expanded and the conversion efficiency can be increased, as compared to the case where the semiconductor layer 114i is formed using only an amorphous semiconductor or only a crystalline semiconductor. Note that the structure where light enters from the side of the second semiconductor region 123 including an amorphous semiconductor is preferable because light having a wide wavelength range can be efficiently utilized.

Moreover, the second semiconductor region 123 has the structure in which the radial crystal 120 and the crystal 118 having a needle-like growing end are included in the amorphous structure 122 formed using an amorphous semiconductor. By the provision of the crystal region in the amorphous semiconductor, it is possible to prevent photogenerated carriers from being trapped in defects such as dangling bonds in the amorphous semiconductor and decreasing the conversion efficiency.

By the structure of the second semiconductor region 123 in which the radial crystal 120 is provided in the amorphous structure 122, a crystal region extending in a direction that is not parallel to the film thickness direction can be formed. By the provision of the crystal region extending in a variety of directions (radially) in the amorphous structure 122, the photogenerated carriers generated in the amorphous structure 122 can be collected efficiently and the conversion efficiency can be increased.

Note that the semiconductor layer 114i is formed without intentional addition of an impurity element imparting a conductivity type. Although an impurity element imparting a conductivity type is intentionally or unintentionally included in the semiconductor layer 114i, the concentration of the impurity element in the semiconductor layer 114i is set to be lower than that in each of the first impurity semiconductor layer 112n and the second impurity semiconductor layer 124p.

Now, a method for manufacturing the semiconductor layer 114i is described with reference to FIGS. 2A to 2C. In the semiconductor layer 114i, the first semiconductor region 116 which includes a crystalline semiconductor is formed at an initial stage and the second semiconductor region 123 which includes both the radial crystal 120 and the crystal 118 with a needle-like growing end in the amorphous structure 122 is formed at a later stage.

FIG. 2A illustrates a state where the process up to the formation of the first semiconductor region 116 over the first impurity semiconductor layer 112n is completed. The first semiconductor region 116 is formed using a crystalline semiconductor, typically a microcrystalline semiconductor.

The microcrystalline semiconductor can be formed by a CVD method, typically a plasma CVD method, using a reaction gas with a mixture ratio (gas flow ratio) that allows formation of the microcrystalline semiconductor. As the reaction gas, a semiconductor source gas and a dilution gas are used. The microcrystalline semiconductor can be formed by controlling the mixture ratio (gas flow ratio) between the semiconductor source gas and the dilution gas so that the formation of the microcrystalline semiconductor is possible. Specifically, a semiconductor source gas and a dilution gas are introduced into a reaction chamber with a mixture ratio that allows formation of the microcrystalline semiconductor and plasma is generated, so that deposition is performed. Accordingly, the first semiconductor region 116 is formed using the microcrystalline semiconductor. For example, the microcrystalline semiconductor can be formed using a reaction gas in which the gas flow ratio of the dilution gas to the semiconductor source gas is 10 times or more and 200 times or less, preferably 50 times or more and 150 times or less. Note that the gas flow ratio in this specification refers to the flow ratio of a gas to be introduced into a reaction chamber.

As the semiconductor source gas, there are silicon hydride typified by silane and disilane, silicon chloride such as SiH₂Cl₂, SiHCl₃, and SiCl₄, and silicon fluoride such as SiF₄. As the dilution gas, there is hydrogen, typically. Moreover, a rare gas such as helium, argon, krypton, and neon can be given as the dilution gas. As the dilution gas, hydrogen or a rare gas, or a combination of hydrogen and a rare gas can be used; alternatively, a plurality of rare gases may be used in combination.

The microcrystalline semiconductor can be formed using the aforementioned reaction gas by a plasma CVD apparatus in which plasma is generated by applying a high-frequency electric power with a frequency of 1 MHz or more and 200 MHz or less. Instead of the high-frequency electric power, a microwave electric power with a frequency of 1 GHz or more and 5 GHz or less, typically 2.45 GHz may be applied. For example, the microcrystalline semiconductor can be formed using glow discharge plasma in a reaction chamber of a plasma CVD apparatus with the use of a mixture of silicon hydride (typically, silane) and hydrogen. The glow discharge plasma is generated by applying high-frequency power with a frequency of 1 MHz or more and 20 MHz or less, typically 13.56 MHz, or high-frequency power with a frequency of 20 MHz or more up to about 120 MHz in the VHF band, typically 27.12 MHz or 60 MHz. Further alternatively, the microcrystalline semiconductor can be formed by a plasma CVD apparatus in which plasma is generated by applying a pulse-modulated electric power (high-frequency electric power).

An example of a condition for forming the first semiconductor region 116 is described. Here, an example is described in which the first semiconductor region 116 is formed using a microcrystalline semiconductor with a columnar grown structure in a parallel-plate plasma CVD apparatus. As for the flow ratio of the reaction gas, silane (SiH₄):hydrogen (H₂)=4:400 (sccm). Moreover, the plasma CVD apparatus is set as follows: the oscillation frequency is 60 MHz, the electric power applied to a parallel-plate electrode is 15 W, the pressure in a reaction chamber is 100 Pa, the distance between electrodes is 20 mm, and the substrate temperature is 280° C.

When the first impurity semiconductor layer 112n formed using a microcrystalline semiconductor layer serves as a seed crystal, the first semiconductor region 116 can be easily formed using a microcrystalline semiconductor.

Next, a plurality of semiconductor particles 117 is formed over the first semiconductor region 116. FIG. 2B illustrates a state where the semiconductor particles 117 are dispersed over the first semiconductor region 116.

The semiconductor particles 117 are particles of a crystalline semiconductor. Specifically, crystalline microparticles including silicon mainly are preferable. For example, silicon microparticles (also referred to as nanosilicon), microparticles of silicon carbide, and the like are given; microparticles of single crystal silicon are more preferable. The size of each semiconductor particle 117 is set so as not to exceed the thickness of the second semiconductor region 123 and is set, for example, in the range of about 5 nm to 100 nm, preferably about 8 nm to 15 nm. Note that as the semiconductor particle 117, a particle which does not intentionally include an impurity element imparting a conductivity type can be used. Alternatively, a particle which intentionally or unintentionally includes an impurity element imparting a conductivity type can be used. For example, as the semiconductor particle 117, a particle including a Group 13 element in the periodic table (such as boron or aluminum) or a Group 15 element in the periodic table (such as phosphorus, arsenic, or antimony) is used.

There is no particular limitation on a method for attaching the semiconductor particles 117 as long as the semiconductor particles 117 are attached onto the first semiconductor region 116. For example, the semiconductor particles 117 in a powder state may be attached onto the first semiconductor region 116 or a solution in which the semiconductor particles 117 are dispersed may be applied onto the first semiconductor region 116.

Next, a semiconductor layer is formed over the first semiconductor region 116 and the semiconductor particles 117, so that the second semiconductor region 123 is formed. In this manner, the semiconductor layer 114i is obtained.

FIG. 2C illustrates a state where, over the first semiconductor region 116, the second semiconductor region 123 including both the radial crystal 120 and the crystal 118 having a needle-like growing end in the amorphous structure 122 is formed.

The semiconductor layer is formed over the first semiconductor region 116 over which the semiconductor particles 117 are dispersed. At the same time as the deposition of the semiconductor layer over the first semiconductor region 116 and the semiconductor particles 117, the semiconductor particles 117 and the crystalline semiconductor (columnar crystal 115) of the first semiconductor region 116 are made to grow, so that the second semiconductor region 123 including both the radial crystal 120 and the crystal 118 having a needle-like growing end in the amorphous structure 122 is formed. The semiconductor layer is deposited over the first semiconductor region 116 in such a manner that a reaction gas (a semiconductor source gas and a dilution gas) is introduced to a reaction chamber at the initial stage of the deposition with a flow ratio that is approximately the same as that when the first semiconductor region 116 is formed, and then the flow ratio of the semiconductor source gas to the dilution gas to be introduced to the reaction chamber is increased in a stepwise manner. The deposition while the semiconductor source gas is increased is performed without stopping the generation of plasma. Specifically, at the initial stage of the deposition, the semiconductor source gas and the dilution gas are introduced to the reaction chamber with a mixture ratio that allows the formation of the microcrystalline semiconductor and plasma is generated to perform the deposition. Then, the deposition is continued while the flow ratio of the semiconductor source gas to the dilution gas to be introduced to the reaction chamber is increased in a stepwise manner until the mixture ratio allows the formation of the amorphous semiconductor at the later stage of the deposition. By the deposition performed in this manner, the semiconductor region having a larger proportion of an amorphous semiconductor than a crystalline semiconductor and including the crystal having a plurality of portions extending radially (radial crystal) and the crystal having a needle-like growing end in the amorphous semiconductor can be formed. Note that at the initial stage of the deposition, the microcrystalline semiconductor can grow in a manner similar to the first semiconductor region 116.

By increasing the flow ratio of the semiconductor source gas to the dilution gas, the growth of the amorphous semiconductor becomes dominant, so that the proportion of an amorphous structure (amorphous semiconductor) becomes large as the film thickness increases. As compared with the crystalline semiconductor such as a microcrystalline semiconductor, the amorphous semiconductor has a higher growth rate. Therefore, as the film thickness increases, the radial crystal 120 and the crystal 118 having a needle-like growing end come to be embedded in the amorphous structure 122.

The radial crystal 120 can be obtained by forming the semiconductor layer over the first semiconductor region 116 and the semiconductor particles 117 and at the same time, making the crystals of the semiconductor particles 117 grow. The plurality of radially-extending portions of the radial crystal 120 (portions corresponding to spines when the radial crystal 120 is expressed as a crystal having a sea urchin shape) is formed using the crystalline semiconductor such as a microcrystalline semiconductor, a polycrystalline semiconductor, or a single crystal semiconductor.

The crystal 118 having a needle-like growing end can be obtained by forming the semiconductor layer over the first semiconductor region 116 and at the same time, making the crystal of the first semiconductor region 116 grow. The crystal 118 having a needle-like growing end can be referred to as a crystal that has kept growing while the columnar crystal 115 of the first semiconductor region 116 in the semiconductor layer formed over the first semiconductor region 116 is maintained. As for the crystal 118 having a needle-like growing end, the growing end becomes needle-like because as the flow ratio of the semiconductor source gas is increased, the growth of the amorphous semiconductor becomes dominant and the growing end of the crystal 118 is embedded in the amorphous structure 122.

An example of a condition for forming the second semiconductor region 123 is described. As for the flow ratio of the reaction gas, silane:hydrogen=6:400 (sccm) at the start of the deposition and silane:hydrogen=42:400 (sccm) at the completion of the deposition. Here, the flow ratio of silane, which is the semiconductor source gas, is increased in a stepwise manner by a fixed amount of 2 sccm. The deposition time is 5 minutes in each step. Specifically, the semiconductor layer is deposited by a step of deposition for 5 minutes with a flow ratio of silane at the start of the deposition set to 6 sccm, followed by a step of deposition for 5 minutes with a flow ratio of silane increased by 2 sccm (that is, 8 sccm) and the latter step is repeated until the flow ratio of silane becomes 42 sccm. Note that the condition other than the flow ratio of the semiconductor source gas to the dilution gas is the same as the aforementioned example of the condition for forming the first semiconductor region 116, and a parallel-plate plasma CVD apparatus is used.

The proportions of the amorphous semiconductor forming the amorphous structure 122, and the crystalline semiconductor forming the radial crystal 120 and the crystalline semiconductor forming the crystal 118 having a needle-like growing end can be controlled by changing the deposition condition such as the flow ratio of each gas or the electric power to be applied. In the second semiconductor region 123, light absorption and generation of photogenerated carriers in the amorphous semiconductor of the amorphous structure 122 are made dominant. For that purpose, when the entire second semiconductor region 123 is averaged, the proportion of the amorphous semiconductor is set to be larger than that of the crystalline semiconductor.

As described above, the semiconductor layer 114i according to Embodiment 1 can be obtained through the simple manufacturing process including the deposition of the semiconductor layer by a CVD method, the dispersion of the semiconductor particles, and the deposition of the semiconductor layer by a CVD method.

Note that when the semiconductor layer is formed over the first semiconductor region 116, the proportion of the crystal 118 having a needle-like growing end can be increased by controlling the flow ratio of the reaction gas. Even though the semiconductor particles 117 are not provided, the crystalline semiconductor can be formed at the same or substantially the same proportion as that in the case where the semiconductor particles 117 are provided. However, as compared to the case where the semiconductor particles 117 are provided, the increase in the flow ratio of the semiconductor source gas to the dilution gas needs to be suppressed to be low; therefore, the deposition rate becomes slow. Further, in the case where the semiconductor particles 117 are not provided, the crystal growth in the direction that is not parallel to the film thickness direction is difficult; therefore, there is a concern that the collection efficiency of the photogenerated carriers decreases as compared to the case where the radial crystal 120 having radially-extending portions which include the crystalline semiconductor is provided. Accordingly, the radial crystal 120 is preferably formed by dispersing the semiconductor particles 117 while the semiconductor layer 114i is formed. The semiconductor particles 117 serve as quasi-crystal-nucleus (seed crystal) and the proportion of the crystalline semiconductor in the second semiconductor region 123 can be easily increased.

In the photoelectric conversion device 100 illustrated in FIG. 1, one of the first impurity semiconductor layer 112n having one conductivity type and the second impurity semiconductor layer 124p having a conductivity type opposite to the conductivity type of the first impurity semiconductor layer 112n is a semiconductor layer including an impurity element imparting p-type conductivity and the other is a semiconductor layer including an impurity element imparting n-type conductivity. In Embodiment 1, light enters from the second semiconductor region 123 side; therefore, the first impurity semiconductor layer 112n is an n-type semiconductor layer and the second impurity semiconductor layer 124p is a p-type semiconductor layer. As the impurity element imparting p-type conductivity, boron, aluminum, and the like, which are Group 13 elements in the periodic table, are typically given. As the impurity element imparting n-type conductivity, phosphorus, arsenic, antimony, and the like, which are Group 15 elements in the periodic table, are typically given. Further, each of the first impurity semiconductor layer 112n and the second impurity semiconductor layer 124p is formed using an amorphous semiconductor (specifically, amorphous silicon, amorphous silicon carbide, or the like) or a microcrystalline semiconductor (specifically, microcrystalline silicon or the like).

The first electrode 104 and the second electrode 126 serving as a pair of electrodes which have the unit cell 110 interposed therebetween are formed using light-transmitting electrodes or a combination of a light-transmitting electrode and a reflective electrode. The light-transmitting electrode is formed using a conductive macromolecule or a conductive material such as indium oxide, indium tin oxide (ITO) alloy, zinc oxide, an oxide semiconductor including indium, gallium, and zinc (In—Ga—Zn—O-based amorphous oxide semiconductor (a-IGZO)). Alternatively, the light-transmitting electrode can be formed by forming an ultrathin film of a metal conductive material. The reflective electrode is formed using a conductive material such as aluminum, silver, titanium, tantalum, or copper. At least one of the first electrode 104 and the second electrode 126 is a light-transmitting electrode. In Embodiment 1, light enters from the second semiconductor region 123 side; therefore, the second electrode 126 is a light-transmitting electrode. Further, the first electrode 104 is preferably a reflective electrode.

The substrate 102 is to support the semiconductor layer performing photoelectric conversion and the accompanying components and there is no limitation on the substrate 102 as long as it resists the manufacturing process of the photoelectric conversion device of Embodiment 1. As the substrate 102, for example, a variety of commercially available glass plates such as soda-lime glass, lead glass, strengthened glass, and ceramic glass; a non-alkali glass substrate such as an aluminosilicate glass substrate or a barium borosilicate glass substrate; a quartz substrate; a ceramic substrate; and the like are given. A glass substrate is preferable because cost reduction and area increase can be achieved.

Next, a method for manufacturing the photoelectric conversion device 100 is described. In Embodiment 1, light enters the device in a direction toward (a direction opposite to) the substrate 102 serving as a supporting substrate.

First, the first electrode 104 is formed over the substrate 102.

The first electrode 104 is formed using a conductive material such as aluminum, silver, titanium, tantalum, or copper by a sputtering method, an evaporation method, or the like.

Over the first electrode 104, the first impurity semiconductor layer 112n, the semiconductor layer 114i, and the second impurity semiconductor layer 124p are formed in this order. There is no particular limitation on the thickness of each of the first impurity semiconductor layer 112n, the semiconductor layer 114i, and the second impurity semiconductor layer 124p; for example, the first impurity semiconductor layer 112n is formed using an n-type semiconductor layer with a thickness of 10 nm to 100 nm, the semiconductor layer 114i is formed using a semiconductor layer with a thickness of 100 nm to 2000 nm, and the second impurity semiconductor layer 124p is formed using a p-type semiconductor layer with a thickness of 10 nm to 100 nm.

The first impurity semiconductor layer 112n and the second impurity semiconductor layer 124p are each formed using a semiconductor source gas and a dilution gas as a reaction gas, to which a doping gas is added, by a CVD method, typically a plasma CVD method. As the doping gas, a gas including an impurity element imparting n-type conductivity (typically, a Group 15 element in the periodic table such as phosphorus, arsenic, or antimony) or an impurity element imparting p-type conductivity (typically, a Group 13 element in the periodic table such as boron or aluminum) is used.

One of the first impurity semiconductor layer 112n and the second impurity semiconductor layer 124p is an n-type semiconductor layer and the other is a p-type semiconductor layer. In Embodiment 1, an n-type semiconductor layer is formed as the first impurity semiconductor layer 112; for example, the n-type semiconductor layer is formed by adding phosphine as the doping gas to the reaction gas. Further, a p-type semiconductor layer is formed as the second impurity semiconductor layer 124p; for example, the p-type semiconductor layer is formed by adding diborane as the doping gas to the reaction gas.

As for the semiconductor layer 114i, the first semiconductor region 116 including the crystalline semiconductor is formed as the initial stage. After the semiconductor particles are formed over the first semiconductor region 116, the flow ratio of the reaction gas is controlled so that the flow ratio of the semiconductor source gas to the dilution gas is increased as the later stage, so that the semiconductor layer is formed. In this manner, the second semiconductor region 123 including both the radial crystal 120 and the crystal 118 having a needle-like growing end in the amorphous structure 122 is formed.

The second electrode 126 is formed over the second impurity semiconductor layer 124p.

The second electrode 126 is formed using a conductive material such as indium oxide, indium tin oxide alloy, zinc oxide, or an oxide semiconductor including indium, gallium, and zinc (In—Ga—Zn—O-based amorphous oxide semiconductor (a-IGZO)) by a sputtering method, an evaporation method, or the like. Alternatively, the second electrode 126 can be formed using a conductive macromolecule material by a droplet discharging method or the like.

Depending on the light incidence direction or the like, the electrode materials of the first electrode and the second electrode, the conductivity types of the first impurity semiconductor layer 112n and the second impurity semiconductor layer 124p, and the like can be changed as appropriate.

By the provision of the layer which includes the semiconductor region including the crystalline semiconductor and the semiconductor region including the crystalline semiconductor region in the amorphous structure as a main layer performing photoelectric conversion, the photoelectric conversion device can achieve a synergic effect of the crystalline semiconductor and the amorphous semiconductor. Since the crystalline semiconductor has sensitivity to long wavelengths and the amorphous semiconductor has sensitivity to short wavelengths, the wavelength range of light that can be absorbed can be expanded so as to achieve high efficiency of the photoelectric conversion device. Moreover, since the radial crystal and the crystal having a needle-like growing end are both included in the amorphous semiconductor, the carriers generated in the amorphous semiconductor can be efficiently collected. Further, since the manufacturing process is simple, a highly-efficient photoelectric conversion device can be provided without complicating the manufacturing steps.

Note that the structure described in Embodiment 1 can be implemented in combination with any of the structures described in the other Embodiment and Example in this specification.

### Embodiment 2

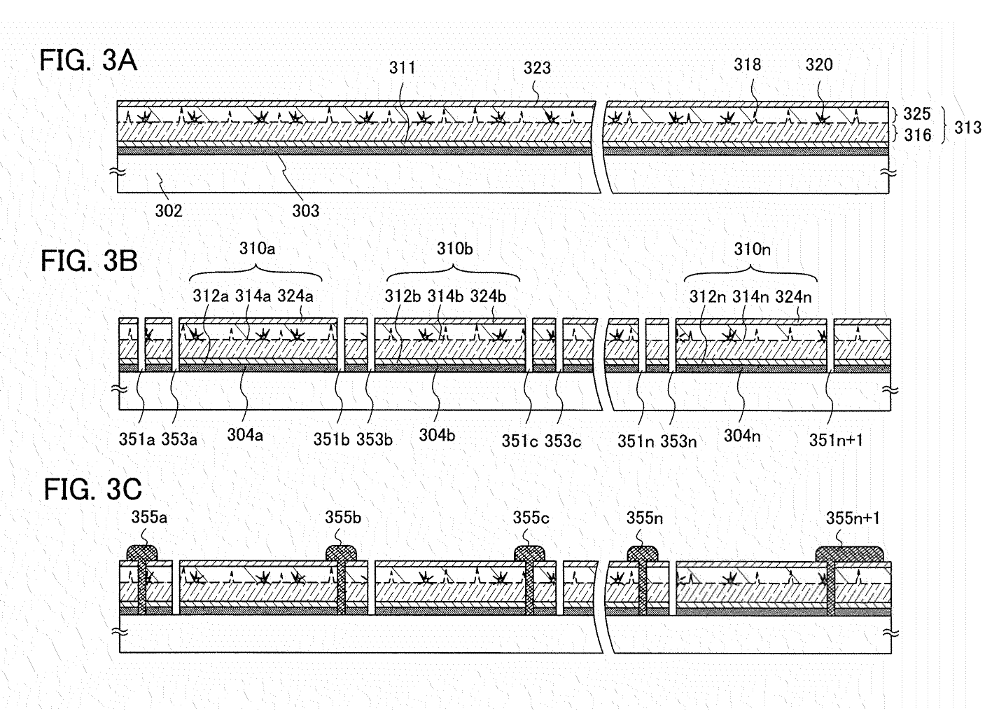

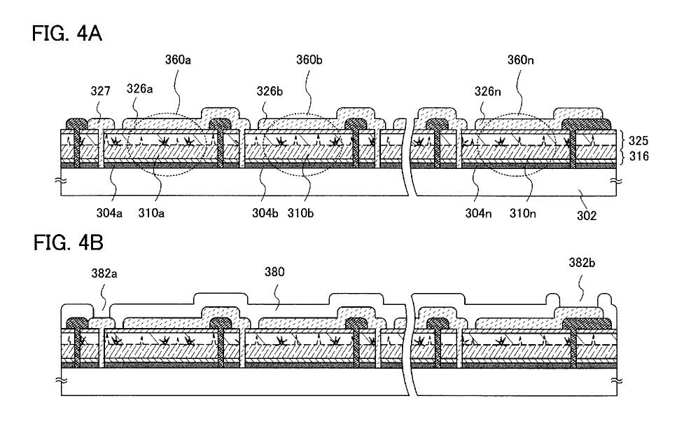

One illustrative embodiment of the present invention is described with reference to FIGS. 3A to 3C and FIGS. 4A and 4B. Embodiment 2 describes an example of an integrated photoelectric conversion device (a photoelectric conversion device module) in which a plurality of photoelectric conversion cells is formed over one substrate and the plurality of photoelectric conversion cells is connected in series for integration. Note that the photoelectric conversion cell includes at least one unit cell. Although a single type, which includes one unit cell, is described with reference to FIGS. 3A to 3C and FIGS. 4A and 4B, a stacked type (including a tandem type), which includes a stack of at least two unit cells, may be used alternatively. A process for manufacturing an integrated photoelectric conversion device and a schematic structure thereof are described below.

In FIG. 3A, a first electrode layer 303 is provided over a substrate 302. Alternatively, the substrate 302 provided with the first electrode layer 303 is prepared. As the first electrode layer 303, a reflective electrode is formed using a conductive material such as aluminum, silver, titanium, tantalum, or copper by a sputtering method, an evaporation method, a printing method, or the like.

A semiconductor junction (typically, a p-i-n junction) is formed by stacking a first impurity semiconductor layer 311, a semiconductor layer 313, and a second impurity semiconductor layer 323 in this order over the first electrode layer 303. As the stack body in which the first impurity semiconductor layer 311, the semiconductor layer 313, and the second impurity semiconductor layer 323 are stacked in this order, the unit cell 110 described in Embodiment 1 can be used.

The first impurity semiconductor layer 311 and the second impurity semiconductor layer 323 are formed by a CVD method (typically, a plasma CVD method). For example, an n-type semiconductor layer is formed as the first impurity semiconductor layer 311 and a p-type semiconductor layer is formed as the second impurity semiconductor layer 323.

The semiconductor layer 313 includes a first semiconductor region 316 on the first impurity semiconductor layer 311 side and a second semiconductor region 325 on the second impurity semiconductor layer 323 side. The first semiconductor region 316 has a larger proportion of a crystalline semiconductor than an amorphous semiconductor, and the second semiconductor region 325 has a larger proportion of an amorphous semiconductor than a crystalline semiconductor. The semiconductor layer 313 can be obtained by a plasma CVD method while the ratio between the semiconductor source gas and the dilution gas which are used as the reaction gas is controlled and by, in the middle of the deposition, forming silicon particles.

The semiconductor layer 313 is formed in a manner similar to the semiconductor layer 114i described in Embodiment 1 and includes both a radial crystal 320 and a crystal 318 having a needle-like growing end in the amorphous structure in the second semiconductor region 325. The crystal 318 having a needle-like growing end may grow until the crystal 318 having a needle-like growing end reaches the second impurity semiconductor layer 323. Note that the semiconductor layer 313 is formed without intentional addition of an impurity element imparting a conductivity type. Even though an impurity element imparting a conductivity type is included intentionally or unintentionally in the semiconductor layer 313, the concentration thereof is set to be lower in the semiconductor layer 313 than in each of the first impurity semiconductor layer 311 and the second impurity semiconductor layer 323.

Next, a plurality of unit cells is formed by separating, for each element, the stack body in which the first impurity semiconductor layer 311, the semiconductor layer 313, and the second impurity semiconductor layer 323 are stacked in this order.

As illustrated in FIG. 3B, openings that penetrate through the stack body including the first impurity semiconductor layer 311, the semiconductor layer 313, and the second impurity semiconductor layer 323, and the first electrode layer 303 are formed; thus, unit cells that are separated from each other for each element are formed. For example, the openings are formed by a laser processing method.

FIG. 3B illustrates an example of forming an opening 351a, an opening 351b, an opening 351c, . . . , an opening 351n+1, an opening 353a, an opening 353b, an opening 353c, . . . , an opening 353n. The openings 351a to 351n+1 are provided for insulation separation, and a unit cell 310a, a unit cell 310b, . . . , a unit cell 310n which are separated for each element by the openings 351a to 351n+1 are formed. The opening 353a, the opening 353b, the opening 353c, . . . , the opening 353n are provided for connection between a first electrode 304a to a first electrode 304n which are divided from each other and second electrodes which are to be formed later.

The unit cell 310a is formed using a stack body including a first impurity semiconductor layer 312a, a semiconductor layer 314a, and a second impurity semiconductor layer 324a. In a similar manner, the unit cell 310b is formed using a stack body including a first impurity semiconductor layer 312b, a semiconductor layer 314b, and a second impurity semiconductor layer 324b, . . . , the unit cell 310n is formed using a stack body including a first impurity semiconductor layer 312n, a semiconductor layer 314n, and a second impurity semiconductor layer 324n. The first electrode layer 303 is also divided by the openings 351a to 351n+1, whereby the first electrode 304a, the first electrode 304b, . . . , the first electrode 304n are formed.

Although FIGS. 3A to 3C illustrate the single type in which one unit cell is formed, the stacked type in which the unit cells are stacked may be employed as described above. In the case of the stacked type, at least one unit cell includes a semiconductor layer which includes a region having a larger proportion of a crystalline semiconductor than an amorphous semiconductor and a region having a larger proportion of an amorphous semiconductor than a crystalline semiconductor and both a radial crystal and a crystal having a needle-like growing end in the amorphous semiconductor (for example, the unit cell 110 described in Embodiment 1). As other examples, there are a stack of the unit cell 110 and a unit cell having a p-i-n junction including an i-layer formed using a microcrystalline semiconductor, a stack of the unit cell 110 and a unit cell having a p-i-n junction including an i-layer formed using an amorphous semiconductor, a stack of the unit cell 110 and a unit cell having a p-i-n junction including an i-layer formed using a single crystal semiconductor, a stack including any of these unit cells, and the like. Alternatively, a plurality of the unit cells 110 may be stacked.

There is no limitation on the kind of lasers used in a laser processing method for forming the openings, but a Nd-YAG laser, an excimer laser, or the like is preferably used. When laser processing is performed in a state that the semiconductor layers (the first impurity semiconductor layer 311, the semiconductor layer 313, and the second impurity semiconductor layer 323) are stacked over the first electrode layer 303, peeling of the first electrode layer 303 from the substrate 302 during the processing can be prevented. This is effective because if the first electrode layer 303 is directly irradiated with a laser beam, the first electrode layer 303 is easily peeled off or ablated.

As illustrated in FIG. 3C, an insulating layer 355a, an insulating layer 355b, an insulating layer 355c, . . . , an insulating layer 355n, and an insulating layer 355n+1 are formed so as to fill the openings 351a to 351n+1 and to cover upper ends of the openings 351a to 351n+1 and vicinity thereof. The insulating layers 355a to 355n+1 can be formed by a screen printing method using a resin material having an insulating property such as an acrylic resin, a phenol resin, an epoxy resin, or a polyimide resin. For example, insulating resin patterns are formed by a screen printing method using a resin composition in which cyclohexane, isophorone, high-resistance carbon black, aerosil, dispersant, a defoaming agent, and a leveling agent are mixed with a phenoxy resin so that the openings 351a to 351n+1 are filled. After the insulating resin patterns are formed, the patterns are thermally cured in an oven at, for example, 160° C. for 20 minutes; as a result, the insulating layers 355a to 355n+1 can be formed.

Next, as illustrated in FIG. 4A, a second electrode 326a, a second electrode 326b, . . . , a second electrode 326n, and a second electrode 327 are formed. Through the steps up to this point, a photoelectric conversion cell 360a in which the first electrode 304a, the unit cell 310a (the first impurity semiconductor layer 312a, the semiconductor layer 314a, and the second impurity semiconductor layer 324a), and the second electrode 326a are stacked in this order; a photoelectric conversion cell 360b in which the first electrode 304b, the unit cell 310b (the first impurity semiconductor layer 312b, the semiconductor layer 314b, and the second impurity semiconductor layer 324b), and the second electrode 326a are stacked in this order; and a photoelectric conversion cell 360n in which the first electrode 304n, the unit cell 310n (the first impurity semiconductor layer 312n, the semiconductor layer 314n, and the second impurity semiconductor layer 324n), and the second electrode 326n are stacked in this order are formed.

The second electrode 326a to the second electrode 326n, and the second electrode 327 are formed by a sputtering method, an evaporation method, or a wet process such as a screen printing method, an ink-jet method, or a dispenser method in which a material that can be discharged is used. As each of the second electrode 326a to the second electrode 326n, and the second electrode 327, a light-transmitting electrode is formed using a conductive composition including a conductive macromolecule or a conductive material such as indium oxide, indium tin oxide alloy, zinc oxide, tin oxide, an alloy of indium tin oxide and zinc oxide, or an oxide semiconductor including indium, gallium, and zinc (In—Ga—Zn—O-based amorphous oxide semiconductor (a-IGZO)).

As the conductive macromolecule included in the conductive composition, a so-called π electron conjugated conductive macromolecule can be used. For example, polyaniline and/or a derivative thereof, polypyrrole and/or a derivative thereof, polythiophene and/or a derivative thereof, and a copolymer of two or more kinds of those materials can be given.

Note that the aforementioned conductive macromolecule is used alone as the conductive composition for the second electrodes 326a to 326n, and the second electrode 327. Alternatively, the aforementioned conductive macromolecule is used as a conductive composition, the properties of which are adjusted by addition of an organic resin, for the second electrodes 326a to 326n, and the second electrode 327. Further, in order to adjust the electrical conductivity of the conductive composition, the redox potential of a conjugated electron of the conjugated conductive macromolecule included in the conductive composition may be changed by doping the conductive composition with an acceptor dopant or a donor dopant.

The second electrodes 326a to 326n and the second electrode 327 can be formed by a wet process in such a manner that the aforementioned conductive composition is dissolved in a solvent such as water or an organic solvent (such as an alcohol-based solvent, a ketone-based solvent, an ester-based solvent, a hydrocarbon-based solvent, or an aromatic-based solvent). The solvent is dried by thermal treatment, thermal treatment wider reduced pressure, or the like. In the case where the properties of the conductive composition have been adjusted by the addition of an organic resin, when the added organic resin is a thermosetting resin, thermal treatment may be further performed after the solvent is dried; when the organic resin is a photo-curable resin, light irradiation treatment may be performed after the solvent is dried.

Further, the second electrodes 326a to 326n and the second electrode 327 can be each formed using a light-transmitting composite conductive material including an organic compound and an inorganic compound. Note that “composite” means not just a state in which two materials are mixed, but a state in which charges can be transported between two (or more than two) materials by mixing the materials.

In specific, the light-transmitting composite conductive material is preferably formed using a composite material including a hole-transporting organic compound and metal oxide exhibiting an electron accepting property with respect to the hole-transporting organic compound. By the use of the light-transmitting composite conductive material including a hole-transporting organic compound and a metal oxide exhibiting an electron accepting property with respect to the hole-transporting organic compound, the resistivity of this light-transmitting composite conductive material can be made 1×10⁶ Ω·cm or less. The hole-transporting organic compound refers to a substance whose hole transporting property is higher than the electron transporting property, and preferably to a substance having a hole mobility of greater than or equal to 10⁻⁶ cm²/Vsec. In specific, a variety of compounds such as an aromatic amine compound, a carbazole derivative, aromatic hydrocarbon, and a macromolecular compound (oligomer, dendrimer, polymer, or the like) can be used. As the metal oxide, transition metal oxide is preferable. Among the transition metal oxide, an oxide of a metal belonging to any of Groups 4 to 8 in the periodic table is preferably used. In specific, vanadium oxide, niobium oxide, tantalum oxide, chromium oxide, molybdenum oxide, tungsten oxide, manganese oxide, and rhenium oxide are preferable because their electron-accepting property is high. Above all, molybdenum oxide is particularly preferable since it is stable in the air, has a low moisture-absorption property, and is easily treated.

The second electrodes 326a to 326n and the second electrode 327 including the light-transmitting composite conductive material can be formed by any method regardless of a dry process or a wet process. For example, by co-evaporation using the above-described organic compound and inorganic compound, the second electrodes 326a to 326n and the second electrode 327 including the light-transmitting composite conductive material can be formed. Alternatively, the second electrodes 326a to 326n and the second electrode 327 can be obtained in such a manner that a solution containing the aforementioned organic compound and metal alkoxide is applied and baked.

In the case of forming the second electrodes 326a to 326n and the second electrode 327 including the light-transmitting composite conductive material, by selecting the kind of the organic compound included in the light-transmitting composite conductive material, the second electrodes 326a to 326n and the second electrode 327 having no absorption peak in an ultraviolet through infrared wavelength range from approximately 450 nm to 800 nm can be formed. Therefore, the light in the absorption wavelength range of the semiconductor layers 314a to 314n can be efficiently transmitted through the second electrodes 326a to 326n and the second electrode 327; thus, the light absorptance of the photoelectric conversion layer can be improved.

As illustrated in FIG. 4A, each of the second electrodes 326a to 326n is electrically connected to each of the first electrode 304b, . . . , the first electrode 304n via the opening 353b, the opening 353c, . . . , the opening 353n. The opening 353b, the opening 353c, . . . , the opening 353n are filled with the same material as the second electrodes 326a to 326n. In this manner, in FIG. 4A, the second electrode 326a of the photoelectric conversion cell 360a is electrically connected to the first electrode 304b of the adjacent photoelectric conversion cell 360b. In a similar manner, the second electrode 326b of the photoelectric conversion cell 360b is electrically connected to the first electrode of the adjacent photoelectric conversion cell, . . . , the second electrode 326n−1 of the photoelectric conversion cell 360n−1 is electrically connected to the first electrode 304n of the adjacent photoelectric conversion cell 360n. In other words, the second electrode 326m (m=a, b, . . . , n−1) of the photoelectric conversion cell 360m is electrically connected to the first electrode 304p (p=b, . . . , n) of the photoelectric conversion cell 360p, and the photoelectric conversion cell 360a, the photoelectric conversion cell 360b, . . . , the photoelectric conversion cell 360n are electrically connected to each other in series.

The second electrode 327 is electrically connected to the first electrode 304a. In the photoelectric conversion cell 360a, the photoelectric conversion cell 360b, . . . , the photoelectric conversion cell 360n which are connected to each other in series, the second electrode 327 serves as one extraction electrode and the second electrode 326n serves as the other extraction electrode. The second electrode 327 serves as an extraction electrode on the first electrodes 304a to 304n side.

In this manner, the photoelectric conversion cell 360a including the first electrode 304a, the unit cell 310a, and the second electrode 326a, . . . , the photoelectric conversion cell 360n including the first electrode 304n, the unit cell 310n, and the second electrode 326n are formed over the same substrate 302. The photoelectric conversion cells 360a to 360n are electrically connected to each other in series.

A resin layer 380 for sealing is formed so as to cover the photoelectric conversion cells 360a to 360n. The resin layer 380 may be formed using an epoxy resin, an acrylic resin, or a silicone resin. Further, an opening 382a is formed through the resin layer 380 over the second electrode 327, and an opening 382b is formed through the resin layer 380 over the second electrode 326n. The second electrode 327 can be connected to an external wiring at the opening 382a. The second electrode 327 serves as an extraction electrode on the first electrode side of the photoelectric conversion cell. The second electrode 326n can be connected to an external wiring at the opening 382b. The second electrode 326n serves as an extraction electrode on the second electrode side of the photoelectric conversion cell.

An integrated photoelectric conversion device can be manufactured using a photoelectric conversion cell including a semiconductor layer which includes a semiconductor region having a larger proportion of a crystalline semiconductor than an amorphous semiconductor and a semiconductor region having a larger proportion of an amorphous semiconductor than a crystalline semiconductor. Each photoelectric conversion cell includes an i-layer including both an amorphous semiconductor and a crystalline semiconductor; therefore, the wavelength range of light that can be absorbed can be expanded and the higher efficiency can be achieved. Further, a radial crystal and a crystal having a needle-like growing end are both included in the amorphous semiconductor, whereby carriers photogenerated in the amorphous semiconductor can also be extracted efficiently. By integration of such photoelectric conversion cells to manufacture a photoelectric conversion device, desired electric power (current and voltage) can be obtained.

The semiconductor layer forming a semiconductor junction, which is a main part of the photoelectric conversion cell, can be formed by a simple process including deposition by a CVD apparatus, dispersion of semiconductor particles, and deposition by a CVD apparatus. A highly-efficient photoelectric conversion device can be provided without complicating the manufacturing process.

Note that the structure described in Embodiment 2 can be implemented in combination with any of the structures described in the other Embodiment and Example in this specification.

### Example

This Example shows results of observation of a sample including a semiconductor layer which includes a semiconductor region (a first semiconductor region) having a larger proportion of a crystalline semiconductor than an amorphous semiconductor and a semiconductor region (a second semiconductor region) having a larger proportion of an amorphous semiconductor than a crystalline silicon.

First, a method for manufacturing the sample observed is described.

A silicon layer was formed over a glass substrate by a parallel-plate plasma CVD apparatus. The manufacturing condition of the silicon layer was as follows: the reaction gas was silane:hydrogen=4 sccm:400 sccm (flow ratio), the oscillation frequency was 60 MHz, the electric power applied to a parallel-plate electrode was 15 W, the pressure in a reaction chamber was 100 Pa, the distance between the electrodes was 20 mm, and the substrate temperature was 280° C.

Silicon particles were dispersed over the silicon layer. As the silicon particles, particles of p-type silicon with a resistivity of 3 Ωcm to 7 Ωcm were used. After the dispersion of the silicon particles, hydrogen plasma treatment was performed using a plasma CVD apparatus. The hydrogen plasma treatment was performed under the following condition: the reaction gas was hydrogen (H₂)=400 sccm, the oscillation frequency was 60 MHz, the electric power applied to a parallel-plate electrode was 15 W, the pressure in a reaction chamber was 100 Pa, the distance between the electrodes was 20 mm, and the substrate temperature was 280° C. Note that the hydrogen plasma treatment was performed in order to remove a native oxide layer and the like on surfaces of the silicon particles.

A silicon layer was formed by a parallel-plate plasma CVD apparatus over the silicon layer over which the silicon particles were dispersed. The manufacturing condition of the silicon layer was as follows: the reaction gas was silane:hydrogen=6 sccm:400 sccm to 42 sccm:400 sccm (flow ratio), the oscillation frequency was 60 MHz, the electric power applied to a parallel-plate electrode was 15 W, the pressure in a reaction chamber was 100 Pa, the distance between the electrodes was 20 mm, and the substrate temperature was 280° C. Specifically, deposition was performed for 5 minutes with silane:hydrogen=6 sccm:400 sccm, the deposition was performed for 5 minutes with silane:hydrogen=8 sccm:400 sccm, and then the deposition for 5 minutes was repeated while the flow rate of silane was increased by 2 sccm until the deposition was performed for 5 minutes with silane:hydrogen=42 sccm:400 sccm.

In order to prevent damage caused during the observation, a carbon film was formed as the uppermost layer of the sample manufactured in the aforementioned manner.

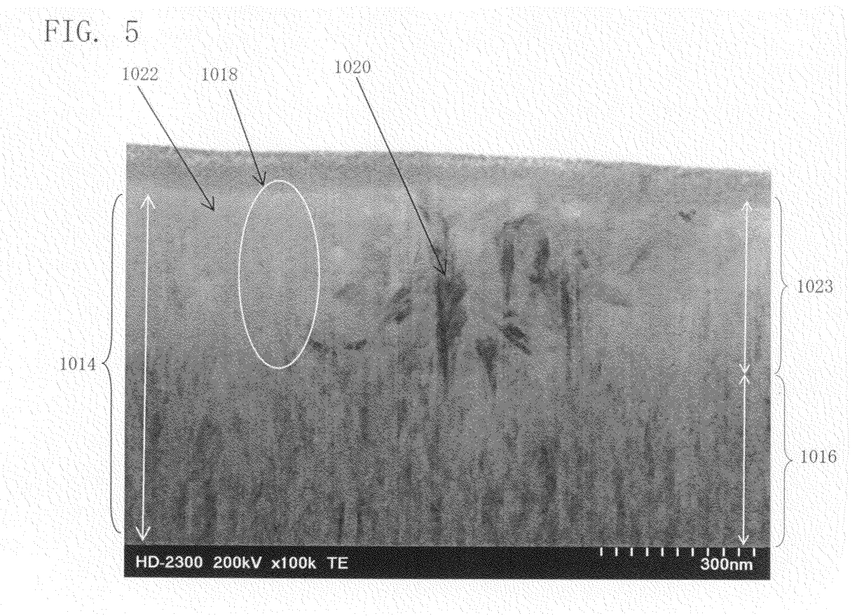

FIG. 5 is a cross-sectional STEM (scanning transmission electron microscope) image taken along a cross section of the sample by a STEM.

In FIG. 5, a state where a silicon layer 1014 having different form of crystal in a lower part and an upper part can be observed. On the lower part (a portion denoted with reference numeral 1016 in FIG. 5), an aggregation of microcrystalline silicon (an aggregation of microcrystalline silicon grown in the film thickness direction to have a columnar shape) can be observed. On the upper part (a portion denoted with reference numeral 1023 in FIG. 5), a crystal grown radially (a portion denoted with reference numeral 1020 in FIG. 5) and a crystal having a needle-like growing end (a portion denoted with reference numeral 1018 in FIG. 5) can be observed. Moreover, a region enclosing the crystal grown radially and the crystal having a needle-like growing end on the upper part (in the portion 1023) is formed using amorphous silicon 1022.

The results of this Example have shown that the semiconductor layer in which the semiconductor including both the crystal grown radially and the crystal having a needle-like growing end in the amorphous semiconductor formed using amorphous silicon is formed can be formed over the crystalline semiconductor formed using microcrystalline silicon. Further, it is also shown that the crystal grown radially and the crystal having a needle-like growing end can be formed by controlling the dispersion of the silicon particles and the flow ratio of the reaction gas, and moreover that the semiconductor layer including the crystalline semiconductor region and the amorphous semiconductor region can be formed.

This application is based on Japanese Patent Application serial No. 2008-303441 filed with Japan Patent Office on Nov. 28, 2008, the entire contents of which are hereby incorporated by reference.

What is claimed is:

1. A photoelectric conversion device comprising:
a unit cell comprising:
a first impurity semiconductor layer having one conductivity type;
a semiconductor layer including:
a first semiconductor region; and
a second semiconductor region,
wherein a proportion of a crystalline semiconductor in the first semiconductor region is larger than a proportion of an amorphous semiconductor in the first semiconductor region,
wherein a proportion of an amorphous semiconductor in the second semiconductor region is larger than a proportion of a crystalline semiconductor in the second semiconductor region,
wherein the second semiconductor region includes both a radial crystal and a crystal having a needle-like growing end in the amorphous semiconductor; and
a second impurity semiconductor layer having a conductivity type opposite to the conductivity type of the first impurity semiconductor layer,
wherein the first impurity semiconductor layer, the semiconductor layer, and the second impurity semiconductor layer are stacked in this order.

2. The photoelectric conversion device according to claim 1,
wherein the crystalline semiconductor is a microcrystalline semiconductor.

3. The photoelectric conversion device according to claim 1,
wherein the radial crystal includes a crystal nucleus and a plurality of portions extending radially from the crystal nucleus, and
wherein the crystal nucleus is a single crystal semiconductor and the portions are a microcrystalline semiconductor.

4. The photoelectric conversion device according to claim 1,
wherein the crystal having the needle-like growing end is a microcrystalline semiconductor.

5. A photoelectric conversion device comprising:
a unit cell comprising:
a first impurity semiconductor layer having one conductivity type;
a semiconductor layer including a crystalline semiconductor and an amorphous semiconductor; and
a second impurity semiconductor layer having a conductivity type opposite to the conductivity type of the first impurity semiconductor layer,
wherein the first impurity semiconductor layer, the semiconductor layer, and the second impurity semiconductor layer are stacked in this order,
wherein a proportion of the crystalline semiconductor on the first impurity semiconductor layer side of the semiconductor layer is larger than a proportion of the amorphous semiconductor on the first impurity semiconductor layer side of the semiconductor layer,
wherein a proportion of the amorphous semiconductor on the second impurity semiconductor layer side of the semiconductor layer is larger than a proportion of the crystalline semiconductor on the second impurity semiconductor layer side of the semiconductor layer, and
wherein the semiconductor layer includes a radial crystal and a crystal having a needle-like growing end in the amorphous semiconductor on the second impurity semiconductor layer side.

6. The photoelectric conversion device according to claim 5,
wherein the crystalline semiconductor is a microcrystalline semiconductor.

7. The photoelectric conversion device according to claim 5,
wherein the radial crystal includes a crystal nucleus and a plurality of portions extending radially from the crystal nucleus, and
wherein the crystal nucleus is a single crystal semiconductor and the portions are a microcrystalline semiconductor.

8. The photoelectric conversion device according to claim 5,
wherein the crystal having the needle-like growing end is a microcrystalline semiconductor.

9. A method for manufacturing a photoelectric conversion device, comprising the steps of:
forming a first electrode over a substrate;
forming a first impurity semiconductor layer having one conductivity type over the first electrode;
forming a semiconductor layer over the first impurity semiconductor layer, the step of forming the semiconductor layer comprising the steps of:
forming a first semiconductor region by introducing a semiconductor source gas and a dilution gas to a reaction chamber with a mixture ratio that allows formation of a microcrystalline semiconductor, generating plasma, and performing deposition over the first impurity semiconductor layer;
forming a semiconductor particle over the first semiconductor region; and
forming a second semiconductor region over the first semiconductor region and the semiconductor particle by introducing a semiconductor source gas and a dilution gas to a reaction chamber with a mixture ratio that allows formation of a microcrystalline semiconductor at an initial stage of deposition, generating plasma, and performing deposition while a flow ratio of the semiconductor source gas to the dilution gas which are introduced to the reaction chamber is increased gradually or in a stepwise manner so that the semiconductor source gas and the dilution gas are introduced to the reaction chamber with a mixture ratio that allows formation of an amorphous semiconductor at a later stage of deposition;
forming a second impurity semiconductor layer having a conductivity type opposite to the conductivity type of the first impurity semiconductor layer over the semiconductor layer; and
forming a second electrode over the second impurity semiconductor layer,
wherein a proportion of a crystalline semiconductor in the first semiconductor region is larger than a proportion of an amorphous semiconductor in the first semiconductor region, and
wherein a proportion of an amorphous semiconductor in the second semiconductor region is larger than a proportion of a crystalline semiconductor in the second semiconductor region.

10. The method for manufacturing a photoelectric conversion device according to claim 9, wherein the second semiconductor region includes a crystal having a plurality of portions extending radially and a crystal having a needle-like growing end, by forming the second semiconductor region over the first semiconductor region and the semiconductor particle.

11. The method for manufacturing a photoelectric conversion device according to claim 9,
wherein a silicon microparticle is used as the semiconductor particle.
